(19) United States
(12) Patent Application Publication
(10) Pub. No.: US 2026/0135519 A1
(43) Pub. Date: May 14, 2026

(54) FLOATING INVERTER AMPLIFIER BASED ON CAPACITOR STACKING AND APPLICATION THEREOF

(71) Applicant: ZHEJIANG UNIVERSITY, Hangzhou (CN)

(72) Inventors: ZHICHAO TAN, HANGZHOU (CN); WEIQIANG CHEN, HANGZHOU (CN)

(21) Appl. No.: 19/324,958

(22) Filed: Sep. 10, 2025

(30) Foreign Application Priority Data
Nov. 11, 2024 (CN) 2024115989566

(51) Int. Cl. H03F 1/26; H03F 1/02; H03F 3/217

(52) U.S. Cl. CPC H03F 1/26; H03F 1/0227; H03F 3/2173; H03F 2200/366; H03F 2200/54

(57) ABSTRACT

Disclosed in the present invention is a floating inverter amplifier based on capacitor stacking, which boosts a power supply of the floating inverter amplifier to 2 times V_{DD} by means of the capacitor stacking; under such condition, a transistor in the inverter may be better turned on, and a cascode structure can be applied to an inverting amplifier operating at a low power supply voltage. Furthermore, an ADC system employing the floating inverter amplifier of the present invention can process an input signal with a common-mode voltage of V_{DD} and an amplitude up to 2 times V_{DD}, which effectively addresses a problem of a reduced input signal amplitude under an ultra-low voltage, thereby increasing a signal-to-noise ratio of the system.

### TECHNICAL FIELD

The present invention belongs to the technical field of amplifiers, and specifically relates to a floating inverter amplifier based on capacitor stacking and an application thereof.

### BACKGROUND TECHNOLOGY

With the continuous advancement of integrated circuit technology, the power supply voltage has gradually decreased, while the threshold voltage of a device does not decrease proportionally with the power supply voltage. Under these conditions, the gate-source voltage and the overdrive voltage of a transistor decrease, causing it to operate more frequently in a sub-threshold region, which in turn leads to issues such as reduced speed and increased noise. Similarly, speed, gain, and swing of an amplifier are also reduced, and noise performance deteriorates. Thus, how to design a higher-performance amplifier under a low power supply voltage has become a challenge.

The main method to increase the overdrive voltage under the low power supply voltage is to reduce the threshold voltage of the transistor or to increase the gate-source voltage of the transistor. The threshold voltage may be reduced by using forward body biasing. However, on the one hand, the forward body biasing causes a parasitic PN junction between the transistor and a substrate to be forward biased, increasing leakage current of the transistor, and on the other hand, it introduces additional noise, affecting the performance of the amplifier. Increasing the gate-source voltage of the transistor may be achieved by capacitive biasing, but this usually introduces additional thermal noise.

For example, the literature of [Liu Baohong, Chen Dongpo, Mao Junfa. A Low-Voltage, Low-Power, Low-Noise Amplifier Using Forward Body Biasing and Gain Enhancement Technique [C]//Chinese Institute of Electronics. Proceedings of the 2009 National Microwave and Millimeter Wave Conference (Volume II). School of Electronic Information and Electrical Engineering, Shanghai Jiao Tong University, 2009:4] proposed an amplifier based on a forward body biasing technology, which connects a body terminal of an N-type MOS transistor to a forward biasing voltage, thereby effectively reducing the threshold voltage of the MOS transistor and increasing the overdrive voltage of the transistor. However, on the one hand, the forward body biasing technology causes the parasitic PN junction between the transistor and the substrate to be forward biased, increasing the leakage current of the transistor, and on the other hand, it introduces additional noise. A Chinese patent application with publication No. CN117728778A proposes a floating inverter amplifier based on a capacitive biasing technology, which increases the gate-source voltage of a transistor by using capacitive biasing, enabling the floating inverter amplifier to operate under a power supply voltage lower than 1V. However, this amplifier requires an additional biasing circuit and also introduces additional sampled thermal noise, affecting the performance of the amplifier.

### SUMMARY OF THE INVENTION

In view of the above, the present invention provides a floating inverter amplifier based on capacitor stacking, wherein the capacitor stacking technology creates a floating power supply of 2 times V_{DD}, thereby increasing the gate-source voltage of the transistor under a low power supply voltage and improving the performance of the amplifier.

A floating inverter amplifier based on capacitor stacking, comprising a differential-structured inverter and a capacitor charge-discharge array, wherein the capacitor charge-discharge array supplies power to the inverter by means of two capacitors that are reset first and then stacked end-to-end.

Further, the inverter comprises two PMOS transistors M₁ and M₂, two NMOS transistors M₃ and M₄, and two switches S₈ and S₉, wherein the source of M₁ and the source of M₂ are connected together and to the floating power rail of the capacitor charge-discharge array, the source of M₃ and the source of M₄ are connected together and to a floating ground rail of the capacitor charge-discharge array, the drain of M₁ and the drain of M₃ and one end of S₈ are connected together as an inverting output terminal of the inverter, the drain of M₂ and the drain of M₄ and one end of S₉ are connected together as a non-inverting output terminal of the inverter, the gate of M₁ and the gate of M₃ are connected together as a non-inverting input terminal of the inverter, the gate of M₂ and the gate of M₄ are connected together as an inverting input terminal of the inverter, the other end of S₈ and the other end of S₉ are connected together and to a power supply voltage V_{DD}, and on/off of the switches S₈ and S₉ are controlled by a clock signal φ₁.

Further, the capacitor charge-discharge array comprises seven switches S₁ to S₇ and two capacitors C_{RES1} and C_{RES2}, wherein one end of S₁ is connected to the power supply voltage V_{DD}, the other end of S₁ is connected to one end of C_{RES1} and one end of S₆, one end of S₂ is connected to the power supply voltage V_{DD}, the other end of S₂ is connected to one end of C_{RES2} and one end of S₅, the other end of S₅ serves as the floating power rail of the capacitor charge-discharge array, the other end of S₆ is connected to the other end of C_{RES2} and one end of S₄, the other end of S₄ is grounded, the other end of C_{RES1} is connected to one end of S₃ and one end of S₇, the other end of S₃ is grounded, the other end of S₇ serves as the floating ground rail of the capacitor charge-discharge array, the on/off of the switches S₁ to S₄ are controlled by the clock signal φ₁, and the on/off of switches S₅ to S₇ are controlled by the clock signal φ₂.

Further, the clock signals φ₁ and φ₂ are complementary in phase and have a certain non-overlapping dead time.

Further, a common-mode voltage of the non-inverting input terminal and the inverting input terminal of the inverter is V_{DD}, the common-mode voltage of the non-inverting output terminal and the inverting output terminal is V_{DD}, and the power supply voltage of the inverter is 2 times V_{DD}.

Further, the inverter is based on a cascode structure, comprising six PMOS transistors M₁, M₂, M₅, M₆, M₇, and M₈, six NMOS transistors M₃, M₄, M₉, M₁₀, M₁₁, and M₁₂, and two switches S₈ and S₉, wherein a source of M₁ and a source of M₂ are connected together and to a floating power rail of the capacitor charge-discharge array, a drain of M₁ is connected to a source of M₅ and a source of M₆, a drain of M₂ is connected to a source of M₇ and a source of M₈, a source of M₃ and a source of M₄ are connected together and to a floating ground rail of the capacitor charge-discharge array, a drain of M₃ is connected to a source of M₉ and a source of M₁₀, a drain of M₄ is connected to a source of M₁₁ and a source of M₁₂, a drain of M₅ and a drain of M₆, a drain of M₉, a drain of M₁₀, and one end of S₈ are connected together as an inverting output terminal of the inverter, a drain of M₇ and a drain of M₈, a drain of M₁₁, a drain of M₁₂, and one end of S₉ are connected together as a non-inverting output terminal of the inverter, a gate of M₁, a gate of M₃, a gate of M₅, a gate of M₈, a gate of M₉, and a gate of M₁₂ are connected together as a non-inverting input terminal of the inverter, a gate of M₂, a gate of M₄, a gate of M₆, a gate of M₇, a gate of M₁₀, and a gate of Mu are connected together as an inverting input terminal of the inverter, the other end of S₈ and the other end of S₉ are connected together and to the power supply voltage V_{DD}, and on/off of the switches S₈ and S₉ are controlled by a clock signal φ₁.

A low power supply voltage discrete-time Δ-Σ analog-to-digital converter, which is composed sequentially from input to output of a switched capacitor array, a first-stage integrator, a second-stage integrator, a switched capacitor analog adder, and an SAR (Successive Approximation Register) quantizer, wherein the first-stage integrator and the second-stage integrator both adopt the above-mentioned floating inverter amplifier based on capacitor stacking.

The floating inverter amplifier based on capacitor stacking boosts the power supply of the floating inverter amplifier to 2 times V_{DD} by means of the capacitor stacking; and under such conditions, a transistor in the inverter may be better turned on, and a cascode structure can be applied to an inverting amplifier operating at a low power supply voltage. Furthermore, an ADC system employing the floating inverter amplifier of the present invention can process an input signal with a common-mode voltage of V_{DD} and an amplitude up to 2 times V_{DD}, which effectively addresses the problem of a reduced input signal amplitude under an ultra-low voltage, thereby increasing the signal-to-noise ratio of the system.

### BRIEF DESCRIPTION OF THE DRAWINGS

FIG. 1 is a schematic of a floating inverter amplifier based on capacitor stacking according to an embodiment of the present invention.

FIG. 2 is a timing diagram of switches in the floating inverter amplifier of the present invention.

FIG. 3 is a schematic of a floating inverter amplifier based on a cascode structure and capacitor stacking in an embodiment of the present invention.

FIG. 4 is a circuit implementation of a 2nd-order 6-bit Δ-Σ analog-to-digital converter in an embodiment of the present invention.

FIG. 5 is a schematic diagram of a chopper switch in the Δ-Σ analog-to-digital converter in an embodiment of the present invention.

FIG. 6 is a schematic diagram of a clock signal generation module in the Δ-Σ analog-to-digital converter in an embodiment of the present invention.

FIG. 7 is an overall timing diagram of the Δ-Σ analog-to-digital converter in an embodiment of the present invention.

### DETAILED DESCRIPTION OF THE EMBODIMENTS

In order to describe the present invention more specifically, the technical solution of the present invention is described in detail in combination with the attached drawings and specific embodiments.

### Example 1

As shown in FIG. 1, the present embodiment provides a floating inverter amplifier based on capacitor stacking for a low power supply voltage discrete-time Delta-Sigma ADC, wherein two capacitors, which are reset first and then stacked end-to-end, supply power to the inverter. The common-mode voltage of its differential input terminals V_{IP} and V_{IN} is a power supply voltage V_{DD}, the common-mode voltage of differential output terminals V_{OP} and V_{ON} is the power supply voltage V_{DD}, and the power supply voltage of the inverter is 2 times the power supply voltage V_{DD}.

A specific structure of the floating inverter amplifier comprises two PMOS transistors M₁ and M₂, two NMOS transistors M₃ and M₄, nine switches S₁ to S₉, and two capacitors C_{RES1} and C_{RES2}. A gate of M₁ and a gate of M₃ are connected to the non-inverting input terminal V_{IP}, while a gate of M₂ and a gate of M₄ are connected to the inverting input terminal V_{IN}. A source of M₁ and a source of M₂ are connected to one end of the switch S₅ and further connected to a floating supply rail V_{SP}. A drain of M₁ and a drain of M₃ are connected together and serve as the inverting output terminal V_{ON}. A source of M₃ and a source of M₄ are connected to one end of the switch S₇ and further connected to a floating ground rail V_{SN}. A drain of M₄ and a drain of M₂ are connected together and serve as the non-inverting output terminal V_{OP}. One end of the switch S₁ is connected to V_{DD}, and the other end of the switch S₁ is connected to one end of the switch S₆ and one end of the capacitor C_{RES1}. The other end of the capacitor C_{RES1} is connected to one end of the switch S₃ and the other end of S₇. The other end of the switch S₃ is connected to ground GND. One end of the switch S₂ is connected to V_{DD}, and the other end of the switch S₂ is connected to the other end of the switch S₅ and one end of the capacitor C_{RES2}. The other end of the capacitor C_{RES2} is connected to the other end of the switch S₆ and one end of the S₄. The other end of the switch S₄ is connected to ground GND. One end of the switch S₈ is connected to the inverting output terminal V_{ON}, and one end of the switch S₉ is connected to the non-inverting output terminal V_{OP}. The other end of the switch S₈ and the other end of the switch S₉ are connected together and to V_{DD}. On/off of the switches S₁ to S₄ and S₈ to S₉ is controlled by a clock signal φ₁, and on/off of the switches S₅ to S₇ is controlled by a clock signal φ₂.

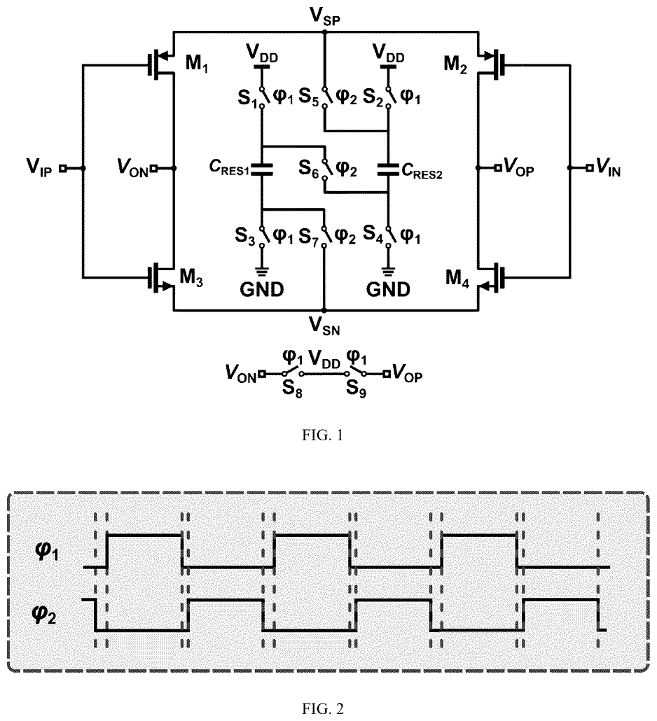

As shown in FIG. 2, the clock signal φ₁ is used to close the switches during a system reset phase, while the clock signal φ₂ is used to close the switches during a system amplification phase. φ₁ and φ₂ are complementary in phase and have a certain non-overlapping period.

### Example 2

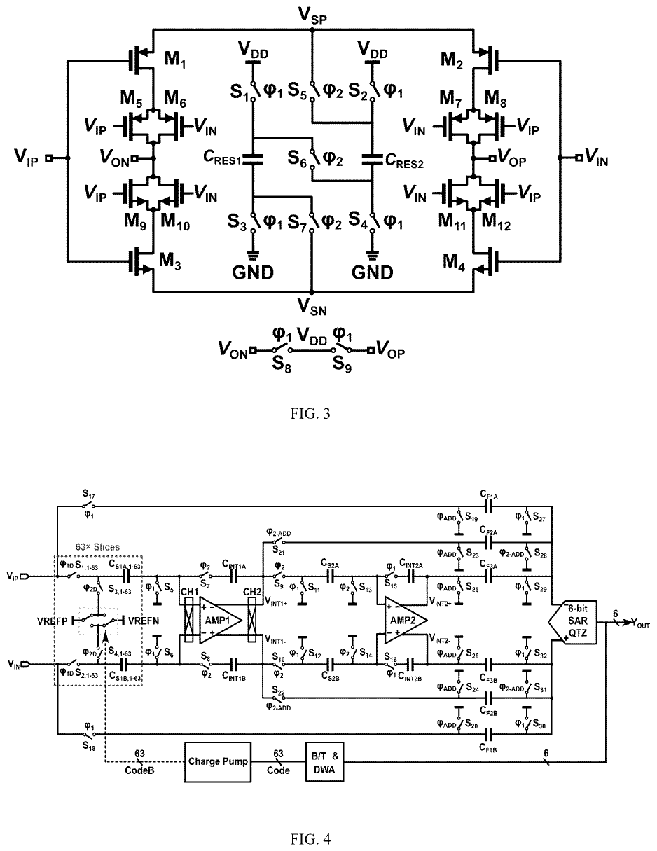

As shown in FIG. 3, the present embodiment provides a floating inverter amplifier based on capacitor stacking and a cascode structure, comprising six PMOS transistors M₁ to M₂ and M₅ to M₈, six NMOS transistors M₃ to M₄ and M₉ to M₁₂, nine switches S₁ to S₉, and two capacitors C_{RES1} and C_{RES2}. Gates of M₁, M₃, M₅, M₈, M₉, and M₁₂ are connected to a non-inverting input terminal V_{IP}, while gates of M₂, M₄, M₆, M₇, M₁₀, and M₁₁ are connected to an inverting input terminal V_{IN}. Sources of M₁ and M₂ are connected to one end of the switch S₅ and further connected to a floating supply rail V_{SP}. A drain of M₁ is connected to sources of M₅ and M₆. Drains of M₅, M₆, M₉, and M₁₀ are connected together and serve as an inverting output terminal V_{ON}. Sources of M₉ and M₁₀ are connected to a drain of M₃. Sources of M₃ and M₄ are connected to one end of the switch S₇ and further connected to a floating ground rail V_{SN}. A drain of M₄ is connected to sources of M₁₁ and M₁₂. Drains of M₇, M₈, M₁₁, and M₁₂ are connected together and serve as a non-inverting output terminal V_{OP}. Sources of M₇ and M₈ are connected to a drain of M₂. One end of the switch S₁ is connected to V_{DD}, and the other end of the switch S₁ is connected to one end of the switch S₆ and one end of the capacitor C_{RES1}. The other end of the capacitor C_{RES1} is connected to one end of the switch S₃ and the other end of S₇. The other end of the switch S₃ is connected to ground GND. One end of the switch S₂ is connected to V_{DD}, and the other end of the switch S₂ is connected to the other end of the switch S₅ and one end of the capacitor C_{RES2}. The other end of the capacitor C_{RES2} is connected to the other end of the switch S₆ and one end of S₄. The other end of the switch S₄ is connected to ground GND. One end of the switch S₈ is connected to the inverting output terminal V_{ON}, and one end of the switch S₉ is connected to the non-inverting output terminal V_{OP}. The other end of the switch S₈ and the other end of the switch S₉ are connected together and to V_{DD}. On/off of the switches S₁ to S₄ and S₈ to S₉ is controlled by a clock signal φ₁, and on/off of the switches S₅ to S₇ is controlled by a clock signal φ₂.

As shown in FIG. 4, the floating inverter amplifier of the present embodiment is applied in a 2nd-order 6-bit Δ-Σ analog-to-digital converter, which comprises a feedback signal selection module, a switched capacitor array, a first-stage integrator, a second-stage integrator, a switched capacitor analog adder, a 6-bit SAR quantizer, a digital logic control unit, a clock signal generation module, and a charge pump module, wherein:

A common-mode voltage of an input signal is V_{DD}, a common-mode voltage of the Δ-Σ analog-to-digital converter is V_{DD}, and reference voltages VREFP and VREFN of the analog-to-digital converter are 2V_{DD} and GND, respectively. The feedback signal selection module controls one end of switches S_{3,1-63} and S_{4,1-63} to connect to VREFP or VREFN according to an output of the digital logic control unit. When an output of the SAR quantizer is k (0≤k≤63), k ports in S_{3,1-63} are connected to VREFP, and 63-k ports are connected to VREFN, while k ports in S_{4,1-63} are connected to VREFN, and 63-k ports are connected to VREFP.

The switched capacitor array consists of 126 unit capacitors C_{S1A,1-63} and C_{S1B,1-63} and 252 switches S_{1,1-63}, S_{2,1-63}, S_{3,1-63}, and S_{4,1-63}, which is equivalent to that C_{S1A}, C_{S1B}, S₁, S₂, S₃, and S₄ consists of 63 identical copies (63×Slices) respectively. One end of the switch S_{1,1-63} and one end of the switch S_{2,1-63} are connected to differential input signals V_{IP} and V_{IN}. The other end of the switch S_{1,1-63} and the other end of the switch S_{3,1-63} are connected to one end of the sampling capacitor C_{S1A,1-63}, and the other end of the switch S_{2,1-63} and the other end of the switch S_{4,1-63} are connected to one end of the sampling capacitor C_{S1B,1-63}. The other ends of the switches S_{3,1-63} and S_{4,1-63} are connected to the feedback signal selection module. On/off of the switches S_{1,1-63} and S_{2,1-63} is controlled by a clock signal ID, and on/off of the switches S_{3,1-63} and S_{4,1-63} is controlled by a clock signal φ_{2D}.

The first-stage integrator comprises a floating inverter amplifier AMP1 based on capacitor stacking and a cascode structure in this embodiment, two integration capacitors C_{INT1A} and C_{INT1B}, a capacitor array, four switches S₅ to S₈, and a set of chopper switches CH1 and CH2. One end of the switch S₅ and one end of the switch S₆ are connected to the capacitor array. One end of the switch S₅, one end of the switch S₇, and one input terminal of the chopper switch CH1 are connected together. The other end of the switch S₅ is connected to the common-mode voltage. The other end of the switch S₇ is connected to one end of the integration capacitor C_{INT1A}. One end of the switch S₆, one end of the switch S₈, and the other input terminal of the chopper switch CH1 are connected together. The other end of the switch S₆ is connected to the common-mode voltage. The other end of the switch S₈ is connected to one end of the integration capacitor C_{INT1B}. The other ends of the integration capacitors C_{INT1A} and C_{INT1B} are respectively connected to two output terminals of the chopper switch CH2. Two output terminals of the chopper switch CH1 are connected to two input terminals of AMP1. Two output terminals of AMP1 are connected to two input terminals of the chopper switch CH2. On/off of the switches S₅ and S₆ are controlled by the clock signal φ₁, and on/off of the switches S₇ and S₈ are controlled by the clock signal φ₂.

The second-stage integrator comprises a floating inverter amplifier AMP2 based on capacitor stacking and a cascode structure in this embodiment, two sampling capacitors C_{S2A} and C_{S2B}, two integration capacitors C_{INT2A} and C_{INT2B}, and eight switches S₉ to S₁₆. One end of the switch S₉ and one end of the switch S₁₀ are connected to the output terminals V_{INT1+} and V_{INT1-} of the first-stage integrator. The other end of the switch S₉, one end of the switch S₁₁, and one end of the sampling capacitor C_{S2A} are connected together. The other end of the switch S₁ is connected to the common-mode voltage. The other end of the sampling capacitor C_{S2A}, one end of the switch S₁₃, one end of the switch S₁₅, and a non-inverting input terminal of AMP2 are connected together. The other end of the switch S₁₃ is connected to the common-mode voltage. The other end of the switch Sis is connected to one end of the integration capacitor C_{INT2A}. The other end of the integration capacitor C_{INT2A} is connected to an inverting output terminal of AMP2. The other end of the switch S₁₀, one end of the switch S₁₂, and one end of the sampling capacitor C_{S2B} are connected together. The other end of the switch S₁₂ is connected to the common-mode voltage. The other end of the sampling capacitor C_{S2B} is connected to one end of the switch S₁₄, one end of the switch S₁₆, and the inverting input terminal of AMP2. The other end of the switch S₁₄ is connected to the common-mode voltage. The other end of the switch S₁₆ is connected to one end of the integration capacitor C_{INT2B}. The other end of the integration capacitor C_{INT2B} is connected to the non-inverting output terminal of AMP2. On/off of the switches S₉, S₁₀, S₁₃, and S₁₄ is controlled by the clock signal φ₂, and on/off of the switches S₁₁, S₁₂, S₁₅, and S₁₆ are controlled by the clock signal φ₁.

The switched capacitor analog adder comprises six feedforward capacitors C_{F1A}, C_{F1B}, C_{F2A}, C_{F2B}, C_{F3A}, C_{F3B}, and sixteen switches S₁₇ to S₃₂. One end of the switch S₁₇ is connected to the input signal V_{IP}. The other end of the switch S₁₇ and one end of the switch S₁₉ are connected to one end of the feedforward capacitor C_{F1A}. The other end of the switch S₁₉ is connected to the common-mode voltage. One end of the switch S₁₈ is connected to the input signal V_{IN}. The other end of the switch S₁₈ and one end of the switch S₂₀ are connected to one end of the feedforward capacitor C_{F1B}. The other end of the switch S₂₀ is connected to the common-mode voltage. One end of the switch S₂₁ is connected to the output terminal V_{INT1+} of the first-stage integrator. The other end of the switch S₂₁ and one end of the switch S₂₃ are connected to one end of the feedforward capacitor C_{F2A}. The other end of the switch S₂₃ is connected to the common-mode voltage. One end of the switch S₂₂ is connected to the output terminal V_{INT1-} of the first-stage integrator. The other end of the switch S₂₂ and one end of the switch S₂₄ are connected to one end of the feedforward capacitor C_{F2B}. The other end of the switch S₂₄ is connected to the common-mode voltage. One end of the switch S₂₅ and one end of the feedforward capacitor C_{F3A} are connected to the output terminal V_{INT2+} of the second-stage integrator. The other end of the switch S₂₅ is connected to the common-mode voltage. One end of the switch S₂₆ and one end of the feedforward capacitor C_{F3B} are connected to the output terminal V_{INT2-} of the integrator. The other end of the switch S₂₆ is connected to the common-mode voltage. The other ends of the feedforward capacitors C_{F1A}, C_{F2A}, C_{F3A} and one end of each of the switches S₂₇ to S₂₉ are connected to the negative input terminal of the SAR quantizer. The other ends of the feedforward capacitors C_{F1B}, C_{F2B}, C_{F3B} and one end of each of the switches S₃₀ to S₃₂ are connected to the positive input terminal of the SAR quantizer. The other ends of the switches S₂₇ to S₃₂ are connected to the common-mode voltage. On/off of the switches S₁₇, S₁₈, S₂₇, S₂₉, S₃₀, and S₃₂ is controlled by the clock signal φ₁. On/off of the switches S₂₁, S₂₂, S₂₈, and S₃₁ is controlled by a clock signal φ_{2-ADD}. On/off of the switches S₁₉, S₂₀, and S₂₃ to S₂₆ is controlled by a clock signal φ_{ADD}.

The SAR quantizer is implemented by using a six-bit successive approximation ADC, which generates an overall system output Y_{OUT}. A signal feedback section comprises a B/T (Binary to Thermometer Code) & DWA (Data Weighted Averaging) module and a charge pump module. The B/T&DWA module first converts the output Y_{OUT} of the SAR quantizer into a thermometer code, then uses an internal register to cyclically shift the thermometer code to generate a module output Code, wherein the bit width of the Code is 63. The charge pump module boosts a high-level voltage of the Code from V_{DD} to twice V_{DD} and outputs CodeB, thereby controlling the switches in the feedback signal selection module.

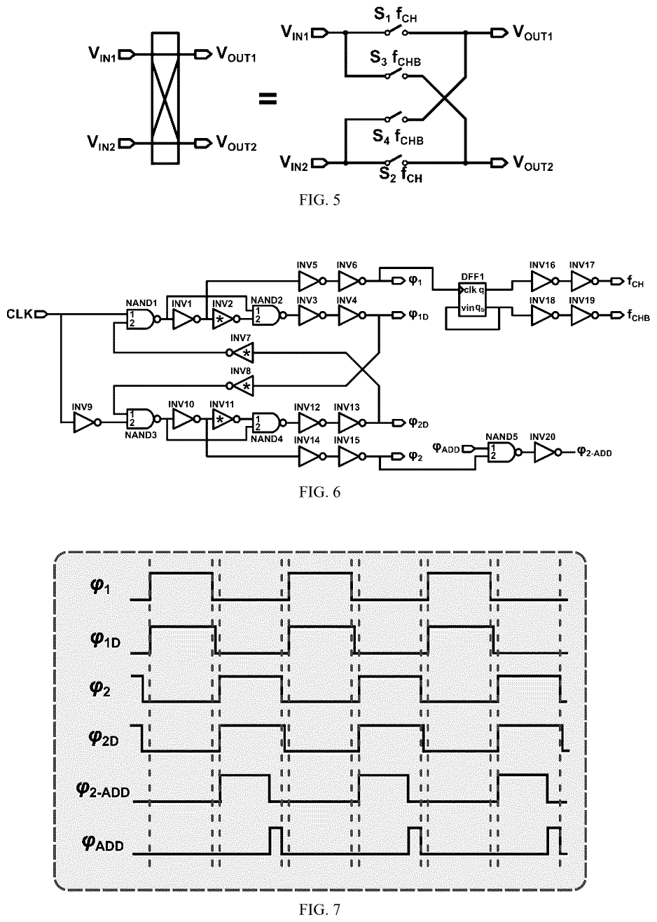

As shown in FIG. 5, the chopper switch comprises four switches S₁˜S₄, wherein one end of each of the switches S₁ and S₃ is connected to V_{IN1}, one end of each of the switches S₂ and S₄ is connected to V_{IN2}, the other end of each of the switches S₁ and S₄ is connected to V_{OUT1}, and the other end of each of the switches S₂ and S₃ is connected to V_{OUT2}. On/off of the switches S₁ and S₂ is controlled by a clock f_{CH}, and on/off of the switches S₃ and S₄ are controlled by a clock f_{CHB}.

As shown in FIG. 6, the clock signal generation module comprises twenty inverters INV1˜INV20, five NAND gates NAND1˜NAND5, and one D flip-flop DFF1. A first input terminal of the NAND gate NAND1 is connected to an input clock CLK. An output terminal of NAND1 is connected to an input terminal of the inverter INV1 and a first input terminal of the NAND gate NAND2. An output terminal of the inverter INV1 is connected to an input terminal of the inverter INV2 and an input terminal of the inverter INV5. An output terminal of the inverter INV2 is connected to a second input terminal of the NAND gate NAND2. An output terminal of the NAND gate NAND2 is connected to an input terminal of the inverter INV3. An output terminal of the inverter INV3 is connected to an input terminal of the inverter INV4. An output terminal of the inverter INV4 is connected to an input terminal of the inverter INV8, and generates a clock φ_{1D}. An output terminal of the inverter INV5 is connected to an input terminal of the inverter INV6. An output terminal of INV6 generates a clock φ₁. An input terminal of the inverter INV9 is connected to an input clock CLK. An output terminal of the inverter INV9 is connected to a second input terminal of the NAND gate NAND3. A first input terminal of NAND3 is connected to an output terminal of INV8. An output terminal of the NAND gate NAND3 is connected to an input terminal of the inverter INV10 and a second input terminal of the NAND gate NAND4. An output terminal of the inverter INV10 is connected to an input terminal of the inverter INV11 and an input terminal of the inverter INV14. An output terminal of the inverter INV11 is connected to a first input terminal of the NAND gate NAND4. An output terminal of the NAND gate NAND4 is connected to an input terminal of the inverter INV12. An output terminal of the inverter INV12 is connected to an input terminal of the inverter INV13. An output terminal of the inverter INV13 is connected to an input terminal of the inverter INV7, and generates a clock φ_{2D}. An output terminal of the inverter INV7 is connected to a second input terminal of the NAND gate NAND1. An output terminal of the inverter INV14 is connected to an input terminal of the inverter INV15. An output terminal of the inverter INV15 is connected to a second input terminal of the NAND gate NAND5, and generates a clock φ₂. A first input terminal of the NAND gate NAND5 is connected to the input clock φ_{ADD}. An output terminal of the NAND gate NAND5 is connected to an input terminal of the inverter INV20. An output terminal of the inverter INV20 generates a clock φ_{2-ADD}. A clk terminal of the D flip-flop DFF1 is connected to the clock φ₁. A vin terminal and a q_{b} terminal of the D flip-flop DFF1 are connected to an input terminal of the inverter INV18. An output terminal of the inverter INV18 is connected to an input terminal of the inverter INV19. An output terminal of the inverter INV19 generates a clock f_{CHB}. A q terminal of the D flip-flop DFF1 is connected to an input terminal of the inverter INV16. An output terminal of the inverter INV16 is connected to an input terminal of the inverter INV17. An output terminal of the inverter INV17 generates a clock f_{CH}.

As shown in FIG. 7, an overall system clock comprises six clocks: φ₁, φ_{1D}, φ₂, φ_{2D}, φ_{2-ADD}, and φ_{ADD}, wherein rising edges of φ₁ and φ_{1D} are aligned; a falling edge of φ_{1D} is delayed relative to φ₁; rising edges of φ₂, φ_{2D}, and φ_{2-ADD} are aligned; a falling edge of φ_{2D} is delayed relative to φ₂; φ₁ and φ₂ are non-overlapping clocks; φ_{2-ADD} and φ_{ADD} are sub-clocks of φ₂; φ_{2-ADD} and φ_{ADD} are non-overlapping clocks; and a falling edge of φ_{ADD} is aligned with a falling edge of φ₂.

In this embodiment, the floating inverter amplifier based on capacitor stacking and a cascode structure can achieve a gain exceeding 40 dB under the low power supply voltage. The discrete-time Δ-Σ analog-to-digital converter employing the inverting amplifier of this embodiment can achieve high precision with an SNDR (signal-to-noise and distortion ratio) exceeding 90 dB.

The above description of embodiments is intended to facilitate understanding and application of the present invention by a person skilled in the art, and obviously, a person familiar with techniques in the art can easily make various modifications to the above embodiments and apply the general principles described herein to other embodiments without creative labor. Therefore, the present invention is not limited to the above embodiments, and an improvement and modification of the present invention made by a person skilled in the field according to the disclosure of the present invention shall be within the protection scope of the present invention.

1. A floating inverter amplifier based on capacitor stacking, comprising a differential-structured inverter and a capacitor charge-discharge array, wherein the capacitor charge-discharge array supplies power to the inverter by means of two capacitors that are reset first and then stacked end-to-end:
wherein the inverter comprises two PMOS transistors M1 and M2, two NMOS transistors M3 and M4, and two switches S8 and S9, wherein a source of M1 and a source of M2 are connected together and to a floating power rail of the capacitor charge-discharge array, a source of M3 and a source of M4 are connected together and to a floating ground rail of the capacitor charge-discharge array, a drain of M1 and a drain of M3 and one end of S8 are connected together as an inverting output terminal of the inverter, a drain of M2 and a drain of M4 and one end of S9 are connected together as a non-inverting output terminal of the inverter, a gate of M1 and a gate of M3 are connected together as a non-inverting input terminal of the inverter, a gate of M2 and a gate of M4 are connected together as an inverting input terminal of the inverter, the other end of S8 and the other end of S9 are connected together and to a power supply voltage VDD, and on/off of the switches S8 and S9 are controlled by a clock signal φ1;
wherein, as an alternative embodiment, the inverter is based on a cascode structure, comprising six PMOS transistors M1, M2, M5, M6, M7, and M8, six NMOS transistors M3, M4, M9, M10, M11, and M12, and two switches S8 and S9, wherein a source of M1 and a source of M2 are connected together and to a floating power rail of the capacitor charge-discharge array, a drain of M1 is connected to a source of M5 and a source of M6, a drain of M2 is connected to a source of M7 and a source of M8, a source of M3 and a source of M4 are connected together and to a floating around rail of the capacitor charge-discharge array, a drain of M3 is connected to a source of M9 and a source of M10, a drain of M4 is connected to a source of M11 and a source of M12, a drain of M5 and a drain of M6, a drain of M9, a drain of M10, and one end of S8 are connected together as an inverting output terminal of the inverter, a drain of M7 and a drain of M8, a drain of M11, a drain of M12, and one end of S9 are connected together as a non-inverting output terminal of the inverter, a gate of M1, a gate of M3, a gate of M5, a gate of M8, a gate of M9, and a gate of M12 are connected together as a non-inverting input terminal of the inverter, a gate of M2, a gate of M4, a gate of M6, a gate of M7, a gate of M10, and a gate of M11 are connected together as an inverting input terminal of the inverter, the other end of S8 and the other end of S9 are connected together and to the power supply voltage VDD, and on/off of the switches S8 and S9 are controlled by a clock signal φ1;
wherein the capacitor charge-discharge array comprises seven switches S1 to S7 and two capacitors CRES1 and CRES2, wherein one end of S1 is connected to the power supply voltage VDD, the other end of S1 is connected to one end of CRES1 and one end of S6, one end of S2 is connected to the power supply voltage VDD, the other end of S2 is connected to one end of CRES2 and one end of S5, the other end of S5 serves as the floating power rail of the capacitor charge-discharge array, the other end of S6 is connected to the other end of CRES2 and one end of S4, the other end of S4 is grounded, the other end of CRES1 is connected to one end of S3 and one end of S7, the other end of S3 is grounded, the other end of S7 serves as the floating around rail of the capacitor charge-discharge array, the on/off of the switches S1 to S4 are controlled by the clock signal φ1, and the on/off of switches S5 to S7 are controlled by the clock signal φ2.

2-4. (canceled)

5. The floating inverter amplifier based on capacitor stacking according to claim 1, wherein the clock signals φ₁ and φ₂ are complementary in phase and have a certain non-overlapping dead time.

6. The floating inverter amplifier based on capacitor stacking according to claim 1, wherein a common-mode voltage of the non-inverting input terminal and the inverting input terminal of the inverter is V_{DD}, the common-mode voltage of the non-inverting output terminal and the inverting output terminal is V_{DD}, and a power supply voltage of the inverter is 2 times V_{DD}.

7. A low power supply voltage discrete-time Δ-Σ analog-to-digital converter, which is composed sequentially from input to output of a switched capacitor array, a first-stage integrator, a second-stage integrator, a switched capacitor analog adder, and an SAR quantizer, wherein the first-stage integrator and the second-stage integrator both adopt the floating inverter amplifier based on capacitor stacking according to 6.

8. The low power supply voltage discrete-time Δ-Σ analog-to-digital converter according to claim 7, wherein the floating inverter amplifier is capable of achieving a gain exceeding 40 dB under a low power supply voltage, and the low power supply voltage discrete-time Δ-Σ analog-to-digital converter is capable of achieving an SNDR exceeding 90 dB.
